(19) United States
(12) Patent Application Publication
(10) Pub. No.: US 2014/0055125 A1
(43) Pub. Date: Feb. 27, 2014

(54) POWER MONITORING DEVICE

(71) Applicants: Dave Irby, Munford, TN (US); Clayton Plymill, Cordova, TN (US)

(72) Inventors: Dave Irby, Munford, TN (US); Clayton Plymill, Cordova, TN (US)

(73) Assignee: KELE, INC., Memphis, TN (US)

(21) Appl. No.: 13/590,743

(22) Filed: Aug. 21, 2012

(51) Int. Cl. G01R 21/00; H01F 38/28

(52) U.S. Cl. 324/120; 324/76.11; 323/358

(57) ABSTRACT

Power monitoring devices, a converter therefor that may be installed in the field, and a kit comprising such a power monitoring device and a converter are disclosed herein. The power monitoring devices may include a housing enclosing circuitry having one or more processors to monitor parameters of a power system and having a plurality of conduits passing therethrough and an electrically conducting plate mounted in the housing in contact with each of the conduits to electrically ground the conduits. The power monitoring device may also include a class two input terminal block for powering the circuitry and a plurality of wires connected thereto that extend out of the housing through such that the device, before installation in the field, can be pre-configured.

### TECHNICAL FIELD

The present application relates to power monitors, more particularly, to an intelligent power monitor that continuously measures voltage and current.

### BACKGROUND

Traditional electric utility meters derive information relating to the energy being supplied to and/or consumed by a customer. In the past, such meters have used rotating pointers as an indication of the total energy consumed. In recent years, meters have been improved to have digital readouts and the capability of performing other functions such as recording of peak demand information, time of use information, load profiles, including per phase and cumulative information such as volts, amps, real power, reactive power, and watt-hour.

Today's meters suffer from the drawback that if housed in a nonmetallic enclosure, the electrician must electrically bond together all conduits entering the enclosure. This is time consuming and puts the electronics at risk of damage if the electrician bumps the circuitry with his tools. Today's meters also suffer from the drawback of requiring factory installation or off-site (i.e., not while in the field) installation of components to add extra capabilities to the meter and on-site configuration of the meter after installation. This is inconvenient and time consuming. Moreover, such meters must be replaced if new features are needed because they are not up-gradable.

### SUMMARY

The power monitoring devices and converter disclosed herein overcome the drawbacks discussed above. For safer and easier installation in the field, the power monitoring devices are equipped with pre-connected conduits for a single connection to a ground wire. To reduce the time spent in the field configuring the power monitoring devices after installation, the devices include connections for a class two power supply via factory installed lead wires such that the device can be pre-configured in the office or the lab. The devices also come equip to accept a converter to change the current transformer signal type that the device can accept and other expansion circuits to provide other capabilities such as network connectivity and other communication protocols. The converter is a field-installable converter, which provides easy adaptation of the device to the power system to be monitored.

In one aspect, the power monitoring devices include a housing enclosing circuitry having one or more processors to monitor parameters of a power system and having a plurality of conduits passing therethrough; and an electrically conducting plate mounted in the housing in contact with each of the conduits to electrically ground the conduits. The housing may be non-metallic and the electrically conducting plate also includes a ground contact for connection to a ground wire. In one embodiment, the electrically conducting plate is positioned between the interior end of the conduits and an interior wall of the housing and includes a one or more holes therethrough that receive the conduits. The plate may be held securely in place by conduit fittings.

In another aspect, the power monitoring device may also include a class two input terminal block housed within the housing for powering the circuitry. In one embodiment, a plurality of wires are connected to the class two input terminal block and extend out of the housing such that the wires are connectable to a class two power supply, before installation of the power monitoring device in the field, to pre-configure the power monitoring device. The housing includes an at least partially removable faceplate, but the wires enable the power monitoring device to be pre-configured without opening the faceplate.

In another aspect, the power monitoring devices include a housing enclosing circuitry having one or more processors to monitor parameters of a power system and current transformer inputs that accept a first type of current transformer signal and include a connector for receiving a converter that alters the current transformer inputs to accept a different type of current transformer signal that is different than the first type of current transformer signal.

In yet another aspect, converters are disclosed that include a connector that is coupleable to the current transformer input terminal block of a power monitoring device, also sometimes referred to herein as the current transformer inputs, a plurality of contacts for connecting to a power system; and one or more components that electrically connect the connector to the contacts. The converters are configured to accept a different type of current transformer signal than the current transformer input terminal block. Accordingly, the converters are connectable to, and in one embodiment are pluggable into, the connector of the current transformer input terminal block or current transformer inputs of the power monitoring devices described above, even after the devices are installed in the field. In one embodiment, the converter changes a 0.333V current transformer input terminal block to a 5-amp current transformer input terminal block.

In another aspect, kits are disclosed herein that include a power monitoring device and a converter, such as those described above. The kit may also include fasteners for securing the converter to the power monitoring device and an optional programming cable.

### BRIEF DESCRIPTION OF THE DRAWINGS

FIG. 1 is a front view of one embodiment of a power monitoring device.

FIG. 2 is photograph of the circuitry and other features within the power monitoring device of FIG. 1.

FIG. 3 is an electrical schematic of the circuitry of the power monitoring device of FIG. 2.

FIG. 4 is a photograph of a 5-amp adaptor board pluggable into the circuitry of the power monitoring device of FIGS. 1 and 2 such that the circuitry can accept conventional 5-amp current transformers.

FIG. 5 is a photograph of the 5-amp adaptor board of FIG. 4 plugged into the circuitry of the power monitoring device of FIG. 2.

FIG. 6 is an electrical schematic of the circuitry of the power monitoring device of FIG. 5 with the 5-amp adaptor board plugged therein.

FIG. 7 is representative of one example of a kit that includes a power monitoring device, converter, and a programming cable.

FIG. 8 are electrical schematics of alternate embodiments of expansion boards that include communication protocols.

### DETAILED DESCRIPTION

The following detailed description will illustrate the general principles of the invention, examples of which are additionally illustrated in the accompanying drawings and photographs. In the figures, like reference numbers typically indicate identical or functionally similar elements.

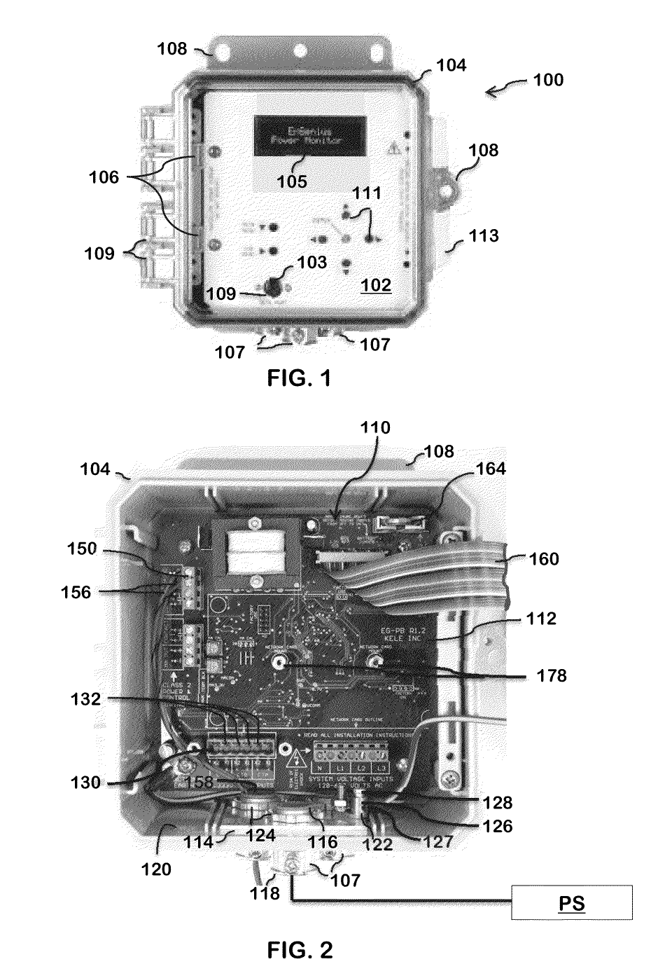

Referring to FIGS. 1-3, a power monitoring device, generally designated 100, is shown that includes one or more processors within its circuitry 110 that can monitor and record numerous power system parameters. The parameters may be monitored for 120V to 600V incoming power supplies without the need of potential transformers and 601V to 32000V with the use of potential transformers. In one embodiment, the power monitoring device 100 can monitor and record over fifty-eight measurable parameters, including, but not limited to, totalized or averaged power system values and per-phase values. This flexibility enables a user to see how well balanced the loads are on a three-phase system, for example, as well as detect a specific problem that might exist on only one phase of the system.

In one embodiment, the circuitry 110 includes a first processor and a second processor. The first processor may be dedicated to monitoring the power of the power system and to running algorithms to convert the readings into understandable, usable values/data. The algorithms may include complex digital signal processing mathematics that create various measurement values from the raw power system waveforms. The second processor may work in tandem with the first processor to store and/or display the values/data and handle other “housekeeping chores” such as driving the display 105, key pad 111, (FIG. 1) generate pulse and milliamp output signals, and interact with any expansion boards (explained below). The second processor may also include excess, available memory to hold firmware for additional features that may be up-loaded in the future (as explained in more detail below).

The power monitoring device 100, as seen in FIG. 1, includes a housing 101 comprising a box 104 and a faceplate 102 attached thereto, which may be pivotally attached to first hinges 106 of the box 104. Housing 101 is typically a mountable housing and may include mounting features 108 and a cover 113 to protect the faceplate 102. The cover 113 is typically made of a clear plastic such that the features of the faceplate 102 are visible through the cover 113. The cover 113 may be pivotally attached to second hinges 109 of the box 104, and the box 104 and the cover 113 both typically are formed of a non-metallic material. In one embodiment, the housing 101 is NEMA 4 rated. NEMA 4, Water Tight & Dust Tight-Indoors/Outdoors, rated enclosures are generally intended for general purpose indoor or outdoor use primarily to provide a degree of protection against windblown dust and rain, splashing water, and hose directed water; and to be undamaged by the formation of ice on the enclosure.

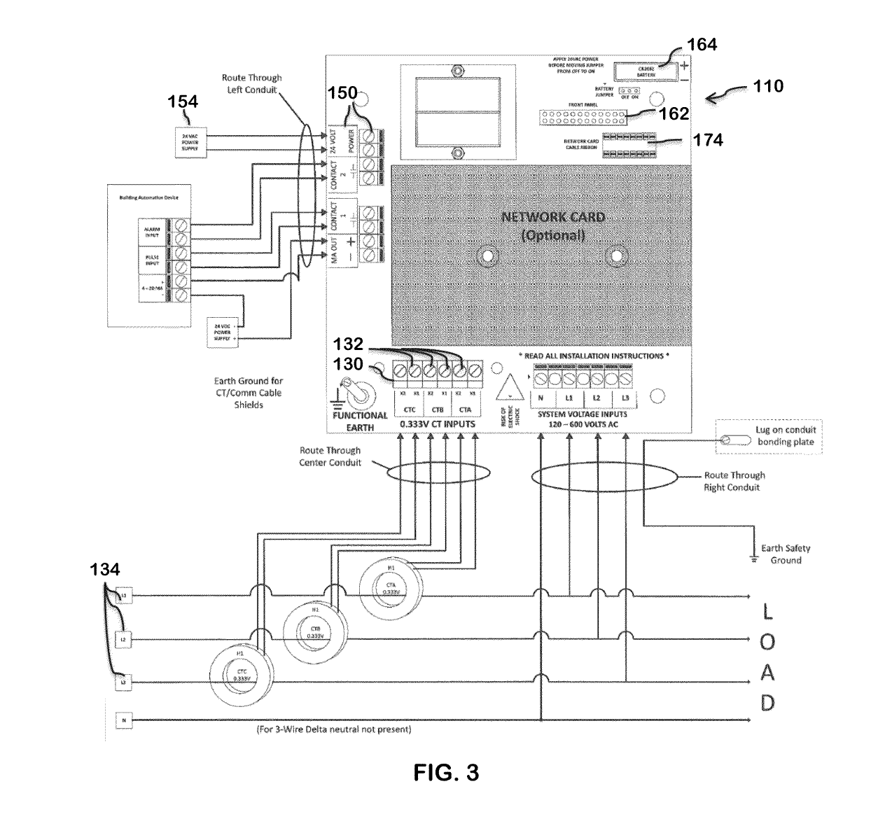

In the embodiment of FIG. 1, the faceplate 102 includes a display 105, a keypad 111, and a data port 103, but the location of such features is not limited to the faceplate 102. Both the display 105 and keypad 111 are connected to the circuitry 110 (FIG. 2) in a way that enable both to continue to function or operate even when the faceplate 102 is open. As see in FIGS. 2 and 3, the display 105 and other features included on/in the faceplate 102 may be connected to the circuitry 110 by a ribbon cable 160 plugged into a ribbon connector 162. The housing 101 may also include one or more conduits 107 entering the housing. One advantage of the housing 101 is that it is provided to the user in a ready to mount configuration that is weather resistant and as such does not require an additional enclosure surrounding the unit. This lowers the total cost of ownership compared to meters which must be housed in an additional enclosure.

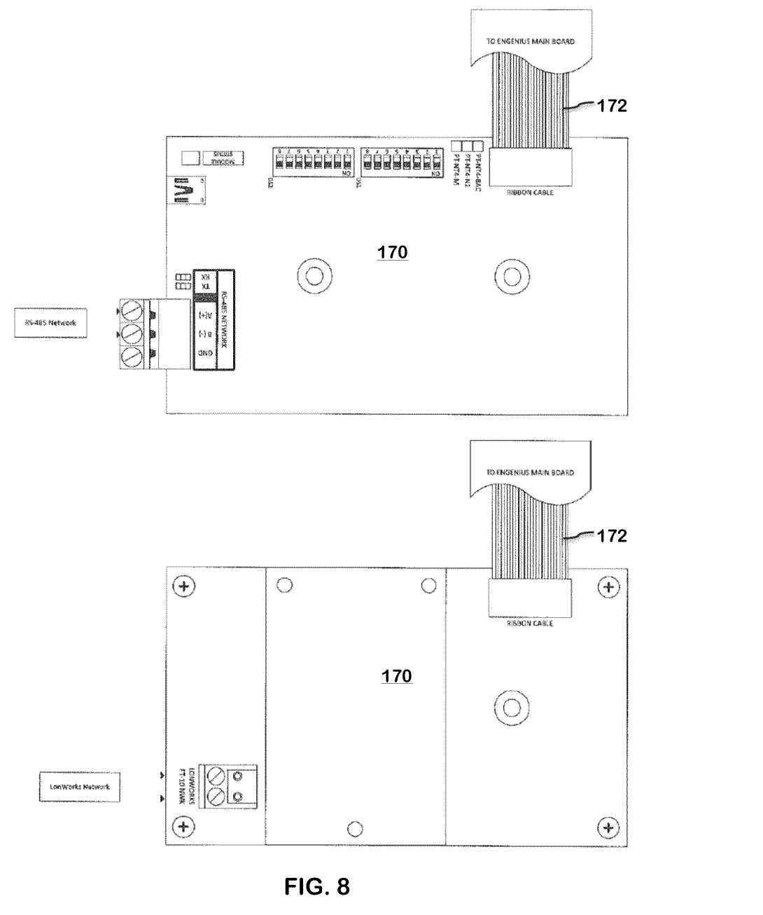

In one embodiment, the one or more processors 112 (FIG. 2) of the circuitry 110 may be configured to enable the end user to select only the parameters or measurements of interest for display. The non-selected parameters or measurements are still available for viewing over a network or through downloading or export via the data port 103 or other communication mechanisms, such as those available through the inclusion of a field installable expansion boards 170 illustrated in FIG. 8. The field installable expansion boards 170 may optionally be pre-selected by the end user and installed by the manufacturer and swapped out at any later date while in the field.

Referring to FIG. 8, the field installable expansion boards 170 each include a second ribbon cable 172 for electrically connecting to the circuitry 110 (FIG. 2). As shown in FIG. 2, circuitry 110 includes a second ribbon connector 174 to receive the second ribbon cable 172 and a designated space for the expansion boards that may include at least a first portion of a fastener 178 to secure the expansion board 170 within the housing 101. The first portion of the fastener 178 may be part of the circuitry 110 or part of the housing 101. In one embodiment, the first portion of the fastener 178 may merely pass through the circuitry 110. In the embodiment of FIG. 2 the first portion of the fastener 178 includes one or more posts (FIGS. 2 and 5) for receiving a second portion of a fastener (not shown). The first portion of the fastener 178 is typically a non-removable, fixed piece and the second portion of the fastener (not shown) is a releasable, removable piece. The second portion of the fastener may be, but not limited to, a screw, a bolt, or a cap such as a screw-on cap or a snap-fit cap that is received in or over the posts. Moreover, as illustrated in FIG. 8, both boards, even though capable of different types of network connections, are interchangeably insertable to the power monitoring device 100 because the expansion boards 170 include the same type of connector.

In one embodiment, the expansion boards 170 are communication boards enabling the power monitoring device 100 to join a network. The expansion boards 170 may be configured to connect the power monitoring device to an RS-485, a BACnet® MS/TP, a Lonworks®, Modbus® RTU, an N2, or any other known or hereinafter developed communication protocols. In another embodiment, the expansion boards may be a cellular modem, Bluetooth® and/or other wireless communications protocol, including accessibility through the Cloud and may include the capability to remotely configure the power monitoring device 100, read data, and/or export data. In yet another embodiment, the expansion boards may be or include additional memory and/or have additional inputs for other meters such as water and gas meters such that the power monitoring device 100 can also monitor parameters related to water and/or gas systems. One of the advantages of the expansion boards and the use of releasable, removable fasteners is that the expansion boards are swappable and new communication protocols can be designed to adapt as technology changes. This feature saves the user from repeatedly buying new units to keep up with the ever changing and rapidly developing communication devices and networks.

In one embodiment, an expansion board 170 in each of a plurality of multiple power monitoring devices 100 may enable each of the devices to be interconnected through a network and provide for one of said plurality of power monitoring devices 100 to be designated as the “master” device. The master device may be able to function as the control for any of the other devices, which may be remotely located relative to the master device. In this manner, the display and key pad or a computer or other electronic device connected to the master device through the data port may be used to monitor, configure, and/or control the remote devices.

As best seen in FIGS. 2 and 3, the circuitry 110 housed within housing 101 includes a class two input terminal block 150 for powering the circuitry 110. The power monitoring device 100 may also include a plurality of wires 156 connected to the class two input terminal block 150 and exiting out through the housing 101. In one embodiment, the housing 101 includes a port 158 (such as, but not limited to one of the conduits 107) through which the wires 156 exit the housing 101. The wires 156 are pre-installed such that the circuitry 110 is connectable to a class two power supply before installation in the field. With these wires 156 a user can attach the power monitoring device 100 to a temporary class two power supply in the shop or at a work bench to preconfigure the device 100 before the device is taken to the job site where it will be mounted to monitor a power system. Since the wires 156 exit the housing 101, the power monitoring device 100 can be preconfigured, as just described, without opening the faceplate 102 and without attaching power wires to the circuitry 110. This provides many advantages to the user such as ease of preconfiguration in the office rather than at the job site, and lower voltage (safer) power supply requirements. The preconfiguration may include setting power system type (1-phase, 3-phase, wye, delta), system voltage, CT ratio, specified intervals for data logging by the circuitry 110 and what data is to be displayed on the display 105.

The power monitoring device 100, see FIG. 2, includes another advantageous feature, an electrically conducting plate 114 mounted within the housing 101 in contact with each of a plurality of conduits 107 to electrically ground the conduits. The conduits 107 have an interior end 116 located within the housing 101 and an exterior end 118 located outside the housing 1010. The conduits 107 each may include a conduit fitting 124 proximate the interior end 116 to secure the conduit 107 relative to the housing 101. As seen in FIG. 2, the electrically conducting plate 114 may be positioned between the interior end 116 of the conduits 107 and an interior wall 120 of the housing 101. The electrically conducting plate 114 preferably includes one or more holes therethrough that are disposed in the plate in an arrangement that is alignable with the conduits 107 such that one conduit is received in each hole in the plate. In an alternate embodiment, the electrically conducting plate 114 may have a single hole shaped and configured to receive all the conduits therethrough that still contacts each conduit at at least one point to electrically connect all the conduits to the electrically conducting plate. One or more conduit fittings 124 may then be used to sandwich the electrically conducting plate 114 between itself and the interior wall of the housing 101. In this manner the electrically conducting plate 114 will be securely held in place. The electrically conducting plate 114 also includes a ground contact 122 for attachment of a ground wire in electrical communication with the electrically conducting plate and as such in electrical communication with each of the conduits 107. The ground contact may be integral with the electrically conducting plate 114 or may be attached thereto. In the embodiment in FIG. 2 the ground contact 122 is a lug 126 extending therefrom that includes a hole 127 for receiving the exposed end of a ground wire (not shown) and a fastener 128 (such as screw or bolt, but not limited thereto) to secure the ground wire to the lug 126.

The electrically conducting plate 114 is pre-installed as described above and results in saving time and material cost for the installation electrician because it eliminates the need for the electrician to install discrete wires to connect each conduit or conduit fitting to one another. The plate 114 automatically bonds the plurality of conduits 107 or conduit fittings 124 together electrically, saving significant labor time. It also eliminates the possibility of the installation electrician damaging the circuitry 110 while installing the conduit fittings 124 or the discrete copper wires.

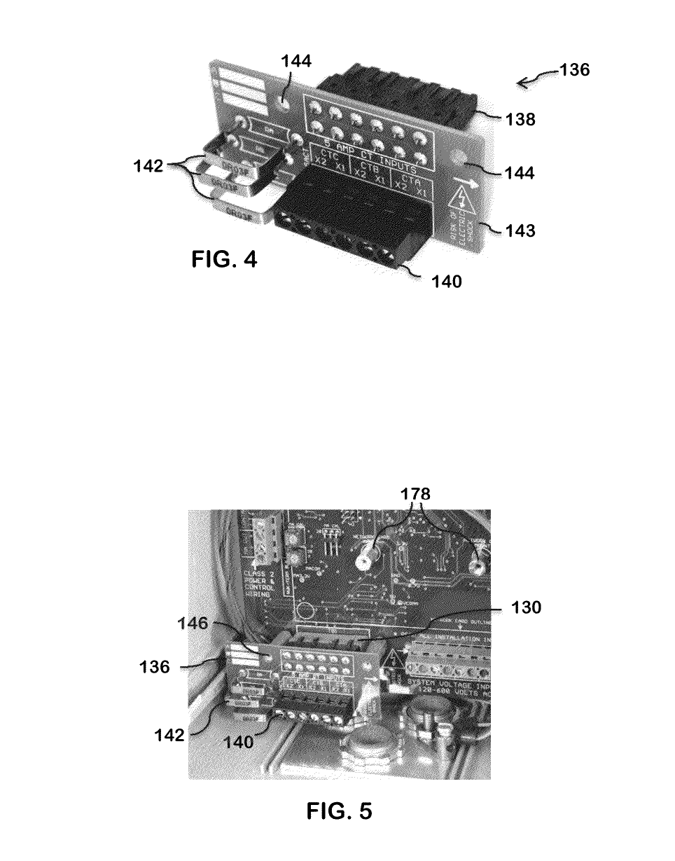

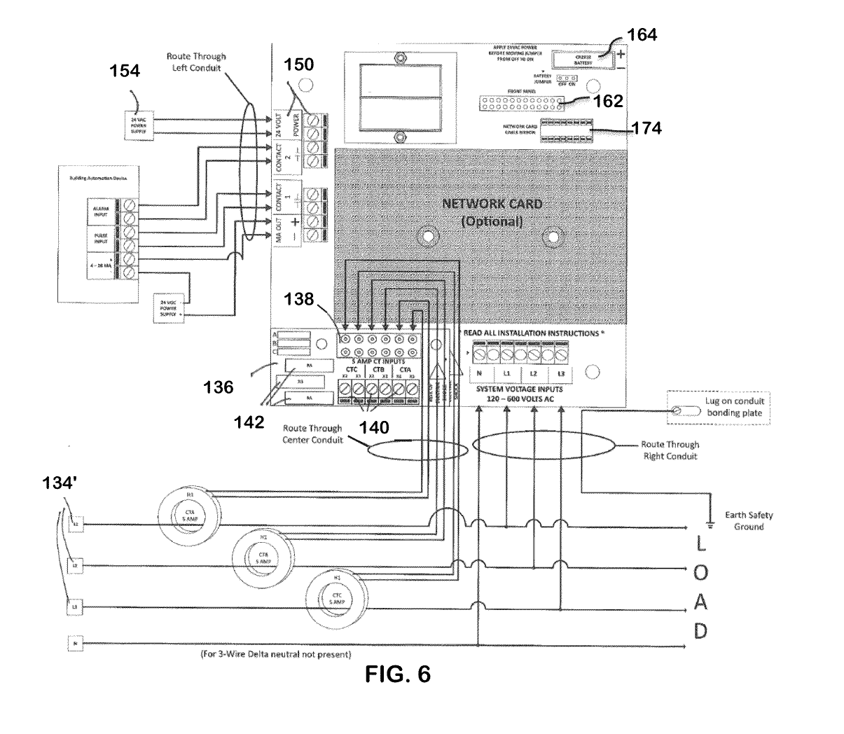

Another advantageous feature of the power monitoring device 100 includes current transformer inputs 130 having a first pluggable member 132 (FIGS. 2 and 3) configured to receive a current transformer converter 136 shown in FIG. 4, even while in the field, that alters the current transformer inputs 130 to accept a different type of current transformer signal 134′ (FIG. 6). In one embodiment, the current transformer inputs 130 of the power monitoring device 100 are 0.333V CT inputs (see FIG. 3) and the current transformer converter 136 changes the 0.333V CT inputs to 5-amp CT inputs (see FIG. 6).

Now referring to FIG. 4, the current transformer converter 136 includes a second pluggable member 138 that is pluggable into a current transformer input terminal block 130 (also interchangeably referred to herein as the current transformer inputs), a plurality of contacts 140 for connecting to a power system, and one or more electrical components 142 electrically connecting the second pluggable member 138 to the contacts 140, for example, resistors, capacitors, diodes, transistors, operational amplifiers, etc. These components of the converter 136 may be interconnected to one another via a board 143 upon which they are all mounted. The board 143 may include one or more holes 144 for receiving a fastener 146 (shown in FIG. 5) that will secure the converter to the circuitry 100 of the power monitoring device 100 after it is plugged into the current transformer input terminal block 130. The converter 136, as mentioned above, is configured to accept a different type of current transformer signal 134′ (FIG. 6) than the current transformer input terminal block 130. In one embodiment, the second pluggable member 138 is at least a six pin male plug or female receptacle and the first pluggable member 132 of the current transformer input terminal block 130 has the opposite configuration such that the first and second pluggable members 132, 138 are pluggable into one another.

When the current transformer converter 136 is plugged into the current transformer input terminal block 130 as shown in FIG. 5, the fasteners 146 secure the converter to the circuitry 100 within the housing 101.

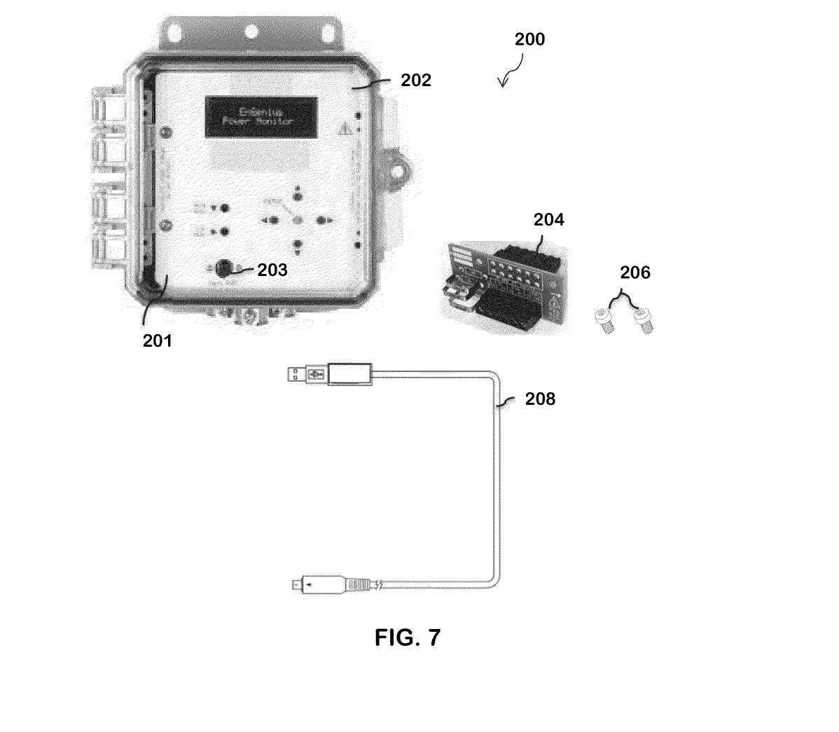

The power monitoring device 100 may be sold as a kit as seen in FIG. 7. The kit 200 includes a power monitoring device 202, such as the power monitoring device 100 described above, a current transformer converter 204, such as the converter 136 described above, available to be plugged into the circuitry within the power monitoring device 202, and one or more fasteners 206 to secure the current transformer converter 204 to the circuitry. The kit may also include a programming cable 208 connectable to a data port 203, described above, which may be accessible through the housing 201 of the power monitoring device 202.

The programming cable 208 when plugged into the data port 203 on one end and an appropriate device on the other end such as a computer provides the user the ability to read all current measurement values, automatically refresh the read measurement values periodically, read all meter configuration parameters, modify all meter configuration parameters, observe the power system voltage and current waveforms graphically, load new version of firmware, and combinations thereof. The data port 203 provides the ability to upgrade the software, including the firmware, in the processors in the field or in the shop before installation in the field. The advantage of the data port 203 is that the user can receive new version of firmware, for example via e-mail, and the customer can upgrade the power monitoring device 100 at any time thereafter.

Other features of the power monitoring device 100 include on-board data logging through nonvolatile memory where the measurements and/or measure parameters can be stored, the ability to export the data from the data logging as comma-separated data for further display and analysis, and a real-time clock and calendar for logging data and a back-up battery 164 (FIGS. 2, 3, and 6) so that the correct time and data are maintained across power outages.

It will be appreciated that while the invention has been described in detail and with reference to specific embodiments, numerous modifications and variations are possible without departing from the spirit and scope of the invention as defined by the following claims.

What is claimed is:

1. A power monitoring device comprising:
a non-metallic housing enclosing circuitry having one or more processors to monitor parameters of a power system and having a plurality of conduits passing therethrough; and
an electrically conducting plate mounted in the housing in contact with each of the conduits to electrically ground the conduits.

2. The power monitoring device of claim 1 further comprising a ground contact coupled to and in electrical communication with the electrically conducting plate.

3. The power monitoring device of claim 1 wherein the electrically conducting plate is positioned between the interior end of the conduits and an interior wall of the housing and includes a one or more holes therethrough that receive the conduits.

4. The power monitoring device of claim 3 further comprising a conduit fitting on the interior end of at least one of the conduits to sandwich the electrically conducting plate between the conduit fitting and the interior wall of the housing.

5. A power monitoring device comprising:
a housing enclosing circuitry having one or more processors to monitor parameters of a power system and one or more conduits passing therethrough for connecting the circuitry to the power system;
wherein the circuitry includes current transformer inputs having a connector configured to receive a converter that alters the current transformer inputs to accept a different type of current transformer signal.

6. The power monitoring device of claim 5 further comprising the converter connected to the connector of the current transformer inputs.

7. The power monitoring device of claim 6 wherein the current transformer inputs of the power monitoring device are 0.333 V CT inputs and the converter changes the 0.333V CT inputs to 5-amp CT inputs.

8. The power monitoring device of claim 6 wherein the converter is pluggable into the connector of the current transformer inputs while in the field.

9. The power monitoring device of claim 8 wherein the connector is at least a six pin male plug or female receptacle.

10. A kit for monitoring a power system, the kit comprising:
a housing enclosing circuitry having one or more processors to monitor parameters of a power system and one or more conduits passing therethrough for connecting the circuitry to the power system; wherein the circuitry includes a current transformer input that accepts a first current transformer signal type and has a first pluggable member; and
a converter comprising a second pluggable member that is pluggable into the first pluggable member of the current transformer input and one or more contacts for connecting to the power system, wherein the converter is configured to accept a second current transformer signal type that is different than the first current transformer signal type.

11. The kit of claim 10 wherein the first current transformer signal type is a 0.333 V CT and the second current transformer signal type is a 5-amp CT.

12. The kit of claim 10 wherein the converter is pluggable into the current transformer inputs while in the field.

13. The kit of claim 12 wherein the housing includes a faceplate that is at least partially removable to provide access to the first pluggable member of the current transformer inputs.

14. The kit of claim 13 wherein the housing includes hinges and the faceplate is pivotally attached to the hinges.

15. The kit of claim 10 wherein the housing includes a data port electrically coupled to the circuitry, and the kit further comprises a programming cable connectable to the data port.

16. A current transformer converter comprising:
a connector that is coupleable to a current transformer input terminal block of a power monitoring device;
a plurality of contacts for connecting to a power system; and
one or more electrical components electrically connecting the connector to the contacts;
wherein the converter is configured to accept a different type of current transformer signal than the current transformer input terminal block.

17. The current transformer converter of claim 16 wherein the connector is pluggable into the current transformer input terminal block of a power monitoring device.

18. The current transformer converter of claim 16 wherein the converter changes a 0.333V current transformer input terminal block to a 5-amp current transformer input terminal block.

19. The current transformer converter of claim 16 wherein the connector is at least a six pin male plug or female receptacle.

20. The current transformer converter of claim 16 wherein the one or more electrical components include one or more resistors.

21. A power monitoring device comprising:
a housing enclosing circuitry having one or more processors to monitor parameters of a power system and a port passing therethrough; and
a class two input terminal block housed within the housing for powering the circuitry.

22. The power monitoring device of claim 21 further comprising a plurality of wires connected to the class two input terminal block and extending out of the housing through the port;
wherein the wires are connectable to a class two power supply, before installation of the power monitoring device in the field, to pre-configure the power monitoring device to monitor the parameters of the power system.

23. The power monitoring device of claim 21 wherein the housing includes an at least partially removable faceplate; wherein a pair of wires enables the power monitoring device to be pre-configured without opening the faceplate.

24. The power monitoring device of claim 23 wherein the faceplate comprises a display and a keypad, both of which are operable even when the faceplate is at least partially removed from the housing.
